(19) United States
(12) Patent Application Publication
(10) Pub. No.: US 2026/0063273 A1
(43) Pub. Date: Mar. 5, 2026

(54) HIGH-BRIGHTNESS LASER-PHOSPHOR LIGHTING WITH CCT CONTROL

(71) Applicant: SIGNIFY HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 19/101,187

(22) PCT Filed: Jul. 24, 2023
(86) PCT No.: PCT/EP2023/070398

§ 371 Date: Feb. 4, 2025

(30) Foreign Application Priority Data
Aug. 4, 2022 (EP) 22188711.0

(51) Int. Cl. F21V 9/40; F21V 5/00; F21Y 115/30; H01S 5/00; H01S 5/323

(52) U.S. Cl. CPC F21V 9/40; F21V 5/007; H01S 5/0071; H01S 5/0087; H01S 5/32308; F21Y 2115/30

(57) ABSTRACT

The invention provides a light generating system comprising a first light generating device, a second light generating device, a first luminescent material, and a control system, wherein: (A) the first light generating device comprises a first laser light source and is configured to generate first device light (111) having a first device light peak wavelength (λ1) and having a first spectral power distribution; wherein the first device light peak wavelength (λ1) is selected from the wavelength range of 425-465 nm; (B) the second light generating device comprises a second laser light source and is configured to generate second device light (121) having a second device light peak wavelength (λ2) and having a second spectral power distribution, different from the first spectral power distribution; wherein the second device light peak wavelength (λ2) is selected from the range of 470-490 nm; (C) the first luminescent material is configured in a light receiving relationship with the first light generating device and is configured to convert at least part of the first device light into first luminescent material light having a luminescent material emission centroid wavelength (λc,1) within the green-yellow wavelength range; and the first luminescent material is not configured in a light receiving relationship with the second light generating device; (D) the light generating system is configured to generate system light (1001) comprising one or more of the first device light, the second device light, and the first luminescent material light, wherein the system light has a controllable correlated color temperature; and (E) the control system is configured to control the first light generating device and the second light generating device, such that (a) in a first operational mode of the light generating system the system light has a first correlated color temperature CCT1, wherein CCT1≥4000 K, (b) in a second operational mode of the light generating system the system light has a second correlated color temperature (CCT2), wherein CCT2−CCT1≥1000 K, (c) in at least one of the operational modes, the system light has a correlated color temperature selected from the range of at least 7000 K, and (d) the system light in both operational modes has a color rendering index of at least 70.

### FIELD OF THE INVENTION

The invention relates to a light generating system and to a lighting device comprising such light generating system.

### BACKGROUND OF THE INVENTION

Laser comprising lighting emitting devices are known in the art. US2020/0232919, for instance, describes a method of producing a light emitting device includes: providing a fluorescent material; dividing a plurality of laser elements into a shorter-wavelength group and a longer-wavelength group so that lights emitted from the laser elements in the shorter-wavelength group have peak wavelengths shorter than an excitation peak wavelength of the fluorescent material and lights emitted from the laser elements in the longer-wavelength group have peak wavelengths longer than the excitation peak wavelength of the fluorescent material; and selecting one or more of the laser elements from each of the shorter-wavelength group and the longer-wavelength group in combination with the fluorescent material to produce a light emitting device.

WO2021/063878A1 discloses a light generating device configured to generate device light, and comprising a first laser light source configured to generate blue first light source light, a second laser light source configured to generated green second light source light, a third laser light source configured to generate red third light source light, a fourth laser light source configured to generate blue fourth light source light, a first luminescent material configured to convert at least part of the first light source light into first green/yellow luminescent material light, an optical element configured to combine (i) unconverted first light source light, (ii) the second light source light, the third light source light, (iv) the fourth light source light, and (v) the first luminescent material light, to provide white device light, and a control system configured to control the laser light sources.

### SUMMARY OF THE INVENTION

While white LED sources can give an intensity of e.g. up to about 300 lm/mm²; static phosphor converted laser white sources can give an intensity even up to about 20,000 lm/mm². Ce doped garnets (e.g. YAG, LuAG) may be the most suitable luminescent convertors which can be used for pumping with blue laser light as the garnet matrix has a very high chemical stability. Further, at low Ce concentrations (e.g. below 0.5%) temperature quenching may only occur above about 200° C. Furthermore, emission from Ce has a very fast decay time so that optical saturation can essentially be avoided. Assuming e.g. a reflective mode operation, blue laser light may be incident on a phosphor. This may in embodiments realize almost full conversion of blue light, leading to emission of converted light. It is for this reason that the use of garnet phosphors with relatively high stability and thermal conductivity is suggested. However, also other phosphors may be applied. Heat management may remain an issue when extremely high-power densities are used.

High brightness light sources can be used in applications such as projection, stage-lighting, spot-lighting and automotive lighting. For this purpose, laser-phosphor technology can be used wherein a laser provides laser light and e.g. a (remote) phosphor converts laser light into converted light. The phosphor may in embodiments be arranged on or inserted in a heatsink for improved thermal management and thus higher brightness.

There appears to be a desire to increase the radiant flux of such light emitting devices and/or to increase the efficiency. Further, there is a desire for controllable light emitting devices. Further, there is a desire for controllable high CCT (correlated color temperature) light emitting devices with high radiant fluxes, such as for stage lighting.

Hence, it is an aspect of the invention to provide an alternative light generating system (and/or lighting device), which preferably further at least partly obviates one or more of above-described drawbacks. The present invention may have as object to overcome or ameliorate at least one of the disadvantages of the prior art, or to provide a useful alternative.

According to a first aspect, the invention provides a light generating system (“system”) comprising a plurality of first light generating device, a second light generating device, and a first luminescent material. Further, the light generating system may comprise a control system. In embodiments, the first light generating device may comprises a first laser light source. Especially, the plurality of first light generating devices may be configured to generate first device light having a first device light peak wavelength (λ₁) and having a first spectral power distribution. In specific embodiments, the first device light peak wavelength (λ₁) may be selected from the wavelength range of 425-465 nm. Yet, in embodiments, the second light generating device may comprise a second laser light source. Especially, the second light generating device may be configured to generate second device light having a second device light peak wavelength (λ₂) and having a second spectral power distribution. Especially, the second spectral power distribution may be different from the first spectral power distribution. In specific embodiments, the second device light peak wavelength (λ₂) may be selected from the range of 470-490 nm. Further, in embodiments the first luminescent material may be configured in a light receiving relationship with the first light generating device and may especially be configured to convert at least part of the first device light into first luminescent material light. The first luminescent material light may have a luminescent material emission centroid wavelength (λ_{c,1}) within the green-yellow wavelength range. Especially, in embodiments, however, the first luminescent material may not be configured in a light receiving relationship with the second light generating device. In embodiments, the light generating system may be configured to generate system light comprising one or more of the first device light, the second device light, and the first luminescent material light. Especially, in embodiments the system light may have a controllable correlated color temperature. In embodiments, the control system may be configured to control the first light generating device and the second light generating device, such that (a) in a first operational mode of the light generating system the system light has a first correlated color temperature CCT1, wherein CCT1≥4000 K. Alternatively or additionally, in embodiments, the control system may be configured to control the first light generating device and the second light generating device, such that (b) in a second operational mode of the light generating system the system light has a second correlated color temperature (CCT2), wherein especially CCT2−CCT1≥1000 K. Alternatively or additionally, in embodiments, the control system may be configured to control the first light generating device and the second light generating device, such that (c) in at least one of the operational modes, the system light has a correlated color temperature selected from the range of at least 7000 K. Yet, alternatively or additionally, in embodiments, the control system may be configured to control the first light generating device and the second light generating device, such that, (d) wherein the system light in both operational modes has a color rendering index of at least 70. Hence, especially the invention provides in embodiments a light generating system comprising a first light generating device, a second light generating device, a first luminescent material, and a control system, wherein: (A) the first light generating device comprises a first laser light source and is configured to generate first device light having a first device light peak wavelength (λ₁) and having a first spectral power distribution; wherein the first device light peak wavelength (λ₁) is selected from the wavelength range of 425-465 nm; (B) the second light generating device comprises a second laser light source and is configured to generate second device light having a second device light peak wavelength (λ₂) and having a second spectral power distribution, different from the first spectral power distribution; wherein the second device light peak wavelength (λ₂) is selected from the range of 470-490 nm; (C) the first luminescent material is configured in a light receiving relationship with the first light generating device and is configured to convert at least part of the first device light into first luminescent material light having a luminescent material emission centroid wavelength (λ_{c,1}) within the green-yellow wavelength range; and the first luminescent material is not configured in a light receiving relationship with the second light generating device; (D) the light generating system is configured to generate system light comprising one or more of the first device light, the second device light, and the first luminescent material light, wherein the system light has a controllable correlated color temperature; and (E) the control system is configured to control the first light generating device and the second light generating device, such that (a) in a first operational mode of the light generating system the system light has a first correlated color temperature CCT1, wherein CCT1≥4000 K, (b) in a second operational mode of the light generating system the system light has a second correlated color temperature (CCT2), wherein CCT2−CCT1≥1000 K, (c) in at least one of the operational modes, the system light has a correlated color temperature selected from the range of at least 7000 K, and (d) the system light in both operational modes has a color rendering index of at least 70, especially at least 80.

With such system, it is possible to provide high brightness light with a relatively high correlated color temperature which may also have a controllable correlated color temperature. For instance, in this way a relatively a simple low-cost high-brightness laser-phosphor light generating system with CCT control, e.g. for stage-lighting, may be provided. Further, with the present system, while varying CCT, especially at relatively high correlated color temperatures, the color point may stay relatively close to the black body locus. Further, with the present system it may also be possible to provide system light having a color rendering index (CRI) larger than 70. In embodiments, the CRI may be at least 80, like at least 85. In specific embodiments, the CRI may even be at least 90.

As indicated above, the invention provides a light generating system comprising a first light generating device, a second light generating device, a first luminescent material, and optionally a control system. Here below, first some general aspects in relation to light generating devices (in general) and laser devices (in general), are discussed.

A light generating device may especially be configured to generate device light. Especially, the light generating device may comprise a light source. The light source may especially configured to generate light source light. In embodiments, the device light may essentially consist of the device light. In other embodiments, the device light may essentially consist of converted light source light. In yet other embodiments, the device light may comprise (unconverted) light source light and converted light source light. Light source light may be converted with a luminescent material into luminescent material light and/or with an upconverter into upconverted light (see also below). The term “light generating device” may also refer to a plurality of light generating devices which may provide device light having essentially the same spectral power distributions. In specific embodiments, the term “light generating device” may also refer to a plurality of light generating devices which may provide device light having different spectral power distributions.

The term “light source” may in principle relate to any light source known in the art. It may be a conventional (tungsten) light bulb, a low pressure mercury lamp, a high pressure mercury lamp, a fluorescent lamp, an LED (light emissive diode). In a specific embodiment, the light source comprises a solid state LED light source (such as an LED or laser diode (or “diode laser”)). The term “light source” may also relate to a plurality of light sources, such as 2-2000 (solid state) LED light sources. Hence, the term LED may also refer to a plurality of LEDs. Further, the term “light source” may in embodiments also refer to a so-called chip-on-board (COB) light source. The term “COB” especially refers to LED chips in the form of a semiconductor chip that is neither encased nor connected but directly mounted onto a substrate, such as a PCB. Hence, a plurality of light emitting semiconductor light source may be configured on the same substrate. In embodiments, a COB is a multi LED chip configured together as a single lighting module.

The term “light source” may also refer to a chip scaled package (CSP). A CSP may comprise a single solid state die with provided thereon a luminescent material comprising layer. The term “light source” may also refer to a midpower package. A midpower package may comprise one or more solid state die(s). The die(s) may be covered by a luminescent material comprising layer. The die dimensions may be equal to or smaller than 2 mm, such as in the range of e.g. 0.2-2 mm. Hence, in embodiments the light source comprises a solid state light source. Further, in specific embodiments, the light source comprises a chip scale packaged LED. Herein, the term “light source” may also especially refer to a small solid state light source, such as having a mini size or micro size. For instance, the light sources may comprise one or more of mini LEDs and micro LEDs. Especially, in embodiment the light sources comprise micro LEDs or “microLEDs” or “μLEDs”. Herein, the term mini size or mini LED especially indicates to solid state light sources having dimensions, such as die dimension, especially length and width, selected from the range of 100 μm-1 mm. Herein, the term u size or micro LED especially indicates to solid state light sources having dimensions, such as die dimension, especially length and width, selected from the range of 100 μm and smaller.

The light source may have a light escape surface. Referring to conventional light sources such as light bulbs or fluorescent lamps, it may be an outer surface of a glass or a quartz envelope. For LED's it may for instance be the LED die, or when a resin is applied to the LED die, the outer surface of the resin. In principle, it may also be the terminal end of a fiber. The term escape surface especially relates to that part of the light source, where the light actually leaves or escapes from the light source. The light source is configured to provide a beam of light. This beam of light (thus) escapes from the light exit surface of the light source.

Likewise, a light generating device may comprise a light escape surface, such as an end window. Further, likewise a light generating system may comprise a light escape surface, such as an end window.

The term “light source” may refer to a semiconductor light-emitting device, such as a light emitting diode (LEDs), a resonant cavity light emitting diode (RCLED), a vertical cavity laser diode (VCSELs), an edge emitting laser, etc. The term “light source” may also refer to an organic light-emitting diode (OLED), such as a passive-matrix (PMOLED) or an active-matrix (AMOLED). In a specific embodiment, the light source comprises a solid-state light source (such as an LED or laser diode). In an embodiment, the light source comprises an LED (light emitting diode). The terms “light source” or “solid state light source” may also refer to a superluminescent diode (SLED).

The term LED may also refer to a plurality of LEDs.

The term “light source” may also relate to a plurality of (essentially identical (or different)) light sources, such as 2-2000 solid state light sources. In embodiments, the light source may comprise one or more micro-optical elements (array of micro lenses) downstream of a single solid-state light source, such as an LED, or downstream of a plurality of solid-state light sources (i.e.e. g. shared by multiple LEDs). In embodiments, the light source may comprise an LED with on-chip optics. In embodiments, the light source comprises pixelated single LEDs (with or without optics) (offering in embodiments on-chip beam steering).

In embodiments, the light source may be configured to provide primary radiation, which is used as such, such as e.g. a blue light source, like a blue LED, or a green light source, such as a green LED, and a red light source, such as a red LED. Such LEDs, which may not comprise a luminescent material (“phosphor”) may be indicated as direct color LEDs.

In other embodiments, however, the light source may be configured to provide primary radiation and part of the primary radiation is converted into secondary radiation.

Secondary radiation may be based on conversion by a luminescent material. The secondary radiation may therefore also be indicated as luminescent material radiation. The luminescent material may in embodiments be comprised by the light source, such as an LED with a luminescent material layer or dome comprising luminescent material. Such LEDs may be indicated as phosphor converted LEDs or PC LEDs (phosphor converted LEDs). In other embodiments, the luminescent material may be configured at some distance (“remote”) from the light source, such as an LED with a luminescent material layer not in physical contact with a die of the LED. Hence, in specific embodiments the light source may be a light source that during operation emits at least light at wavelength selected from the range of 380-470 nm. However, other wavelengths may also be possible. This light may partially be used by the luminescent material.

In embodiments, the light generating device may comprise a luminescent material. In embodiments, the light generating device may comprise a PC LED. In other embodiments, the light generating device may comprise a direct LED (i.e. no phosphor). In embodiments, the light generating device may comprise a laser device, like a laser diode. In embodiments, the light generating device may comprise a superluminescent diode. Hence, in specific embodiments, the light source may be selected from the group of laser diodes and superluminescent diodes. In other embodiments, the light source may comprise an LED.

The light source may especially be configured to generate light source light having an optical axis (O), (a beam shape,) and a spectral power distribution. The light source light may in embodiments comprise one or more bands, having band widths as known for lasers

The term “light source” may (thus) refer to a light generating element as such, like e.g. a solid state light source, or e.g. to a package of the light generating element, such as a solid state light source, and one or more of a luminescent material comprising element and (other) optics, like a lens, a collimator. A light converter element (“converter element” or “converter”) may comprise a luminescent material comprising element. For instance, a solid state light source as such, like a blue LED, is a light source. A combination of a solid state light source (as light generating element) and a light converter element, such as a blue LED and a light converter element, optically coupled to the solid state light source, may also be a light source (but may also be indicated as light generating device). Hence, a white LED is a light source (but may e.g. also be indicated as (white) light generating device).

The term “light source” herein may also refer to a light source comprising a solid state light source, such as an LED or a laser diode or a superluminescent diode.

The term “light source” may (thus) in embodiments also refer to a light source that is (also) based on conversion of light, such as a light source in combination with a luminescent converter material. Hence, the term “light source” may also refer to a combination of an LED with a luminescent material configured to convert at least part of the LED radiation, or to a combination of a (diode) laser with a luminescent material configured to convert at least part of the (diode) laser radiation.

In embodiments, the term “light source” may also refer to a combination of a light source, like an LED, and an optical filter, which may change the spectral power distribution of the light generated by the light source. Especially, the term “light generating device” may be used to address a light source and further (optical components), like an optical filter and/or a beam shaping element, etc.

The phrases “different light sources” or “a plurality of different light sources”, and similar phrases, may in embodiments refer to a plurality of solid-state light sources selected from at least two different bins. Likewise, the phrases “identical light sources” or “a plurality of same light sources”, and similar phrases, may in embodiments refer to a plurality of solid-state light sources selected from the same bin.

The term “solid state light source”, or “solid state material light source”, and similar terms, may especially refer to semiconductor light sources, such as a light emitting diode (LED), a diode laser, or a superluminescent diode.

The term “laser light source” especially refers to a laser. Such laser may especially be configured to generate laser light source light having one or more wavelengths in the UV, visible, or infrared, especially having a wavelength selected from the spectral wavelength range of 200-2000 nm, such as 300-1500 nm. The term “laser” especially refers to a device that emits light through a process of optical amplification based on the stimulated emission of electromagnetic radiation.

Especially, in embodiments the term “laser” may refer to a solid-state laser. In specific embodiments, the terms “laser” or “laser light source”, or similar terms, refer to a laser diode (or diode laser).

Hence, in embodiments the light source comprises a laser light source. In embodiments, the terms “laser” or “solid state laser” or “solid state material laser” may refer to one or more of cerium doped lithium strontium (or calcium) aluminum fluoride (Ce:LiSAF, Ce:LiCAF), chromium doped chrysoberyl (alexandrite) laser, chromium ZnSe (Cr:ZnSe) laser, divalent samarium doped calcium fluoride (Sm:CaF₂) laser, Er:YAG laser, erbium doped and erbium-ytterbium codoped glass lasers, F-Center laser, holmium YAG (Ho:YAG) laser, Nd:YAG laser, NdCrYAG laser, neodymium doped yttrium calcium oxoborate Nd: YCa₄O(BO₃)₃ or Nd:YCOB, neodymium doped yttrium orthovanadate (Nd:YVO₄) laser, neodymium glass (Nd:glass) laser, neodymium YLF (Nd:YLF) solid-state laser, promethium 147 doped phosphate glass (147Pm³⁺:glass) solid-state laser, ruby laser (Al₂O₃:Cr³⁺), thulium YAG (Tm:YAG) laser, titanium sapphire (Ti:sapphire; Al₂O₃:Ti³⁺) laser, trivalent uranium doped calcium fluoride (U:CaF₂) solid-state laser, Ytterbium doped glass laser (rod, plate/chip, and fiber), Ytterbium YAG (Yb:YAG) laser, Yb₂O₃ (glass or ceramics) laser, etc.

For instance, including second and third harmonic generation embodiments, the light source may comprise one or more of an F center laser, a yttrium orthovanadate (Nd:YVO₄) laser, a promethium 147 doped phosphate glass (147Pm³⁺:glass), and a titanium sapphire (Ti:sapphire; Al₂O₃:Ti³⁺) laser. For instance, considering second and third harmonic generation, such light sources may be used to generated blue light.

In embodiments, the terms “laser” or “solid state laser” or “solid state material laser” may refer to one or more of a semiconductor laser diodes, such as GaN, InGaN, AlGaInP, AlGaAs, InGaAsP, lead salt, vertical cavity surface emitting laser (VCSEL), quantum cascade laser, hybrid silicon laser, etc.

A laser may be combined with an upconverter in order to arrive at shorter (laser) wavelengths. For instance, with some (trivalent) rare earth ions upconversion may be obtained or with non-linear crystals upconversion can be obtained. Alternatively, a laser can be combined with a downconverter, such as a dye laser, to arrive at longer (laser) wavelengths.

As can be derived from the below, the term “laser light source” may also refer to a plurality of (different or identical) laser light sources. In specific embodiments, the term “laser light source” may refer to a plurality N of (identical) laser light sources. In embodiments, N=2, or more. In specific embodiments, N may be at least 5, such as especially at least 8. In this way, a higher brightness may be obtained. In embodiments, laser light sources may be arranged in a laser bank (see also above). The laser bank may in embodiments comprise heat sinking and/or optics e.g. a lens to collimate the laser light. Hence, in embodiments lasers in a laser bank may share the same optics.

The laser light source is configured to generate laser light source light (or “laser light”). The light source light may essentially consist of the laser light source light. The light source light may also comprise laser light source light of two or more (different or identical) laser light sources. For instance, the laser light source light of two or more (different or identical) laser light sources may be coupled into a light guide, to provide a single beam of light comprising the laser light source light of the two or more (different or identical) laser light sources. In specific embodiments, the light source light is thus especially collimated light source light. In yet further embodiments, the light source light is especially (collimated) laser light source light.

The laser light source light may in embodiments comprise one or more bands, having band widths as known for lasers. In specific embodiments, the band(s) may be relatively sharp line(s), such as having full width half maximum (FWHM) in the range of less than 20 nm at RT, such as equal to or less than 10 nm. Hence, the light source light has a spectral power distribution (intensity on an energy scale as function of the wavelength) which may comprise one or more (narrow) bands.

The beams (of light source light) may be focused or collimated beams of (laser) light source light. The term “focused” may especially refer to converging to a small spot. This small spot may be at the discrete converter region, or (slightly) upstream thereof or (slightly) downstream thereof. Especially, focusing and/or collimation may be such that the cross-sectional shape (perpendicular to the optical axis) of the beam at the discrete converter region (at the side face) is essentially not larger than the cross-section shape (perpendicular to the optical axis) of the discrete converter region (where the light source light irradiates the discrete converter region). Focusing may be executed with one or more optics, like (focusing) lenses. Especially, two lenses may be applied to focus the laser light source light. Collimation may be executed with one or more (other) optics, like collimation elements, such as lenses and/or parabolic mirrors. In embodiments, the beam of (laser) light source light may be relatively highly collimated, such as in embodiments ≤2° (FWHM), more especially ≤1° (FWHM), most especially ≤0.5° (FWHM). Hence, ≤2° (FWHM) may be considered (highly) collimated light source light. Optics may be used to provide (high) collimation (see also above).

The term “solid state material laser”, and similar terms, may refer to a solid state laser like based on a crystalline or glass body dopes with ions, like transition metal ions and/or lanthanide ions, to a fiber laser, to a photonic crystal laser, to a semiconductor laser, such as e.g. a vertical cavity surface-emitting laser (VCSEL), etc.

The term “solid state light source”, and similar terms, may especially refer to semiconductor light sources, such as a light emitting diode (LED), a diode laser, or a superluminescent diode.

Instead of the term “solid state light source” also the term “semiconductor-based light source” may be applied. Hence, the term “semiconductor-based light source” may e.g. refer to one or more of a light emitting diode (LED), a diode laser, and a superluminescent diode.

Hence, the light generating device may comprise one or more of a light emitting diode (LED), a diode laser, and a superluminescent diode.

As indicated above, in embodiments, the first light generating device may comprise a first laser light source, such as a diode laser. In embodiments, the first light generating device may also comprise a plurality of first laser light sources. Especially, the first light generating device is configured to generate first device light having a first device light peak wavelength (λ₁) and having a first spectral power distribution. With the term “spectral power distribution” it is herein especially refer to the spectral power distribution in the visible wavelength range (see further also below). In specific embodiments, the first device light may essentially consist of laser light. In embodiments, the first device light peak wavelength (λ₁) may be selected from the wavelength range of 425-465 nm. Especially, the first device light peak wavelength (λ₁) may be selected from the wavelength range of 430-460 nm, more especially 433-457 nm, such as in embodiments selected from the wavelenght range of 435-455 nm. Though the centroid wavelength may not be essentially have the same value, the centroid wavelength may also be found in about this wavelength, such as 425-465 nm+/−5 nm, such as selected from the wavelength range of 435-455 nm+/−5 nm.

Further, as indicated above, in embodiments, the second light generating device may comprise a second laser light source, such as a diode laser. In embodiments, the second light generating device may also comprise a plurality of second laser light sources.

Especially, the second light generating device is configured to generate second device light having a second device light peak wavelength (λ₂) and having a second spectral power distribution. Especially, the second spectral power distribution may be different from the first spectral power distribution. In specific embodiments, the second device light may essentially consist of laser light. In embodiments, the second device light peak wavelength (λ₂) may be selected from the wavelength range of 460-490 nm, wherein λ₁<λ₂, especially 470-490 nm. In embodiments, the second device light peak wavelength (λ₂) may be selected from the wavelength range of 472-487 nm, more especially 474-485 nm, such as in embodiments selected from the wavelength range of 475-483 nm. Though the centroid wavelength may not be essentially have the same value, the centroid wavelength may also be found in about this wavelength, such as 470-490 nm+/−5 nm, such as selected from the wavelength range of 475-483 nm+/−5 nm. Especially, the color point may stay relatively close to the black body locus, especially at relatively high CCTs, amongst others due to the (controllable) contribution of the second device light to the system light.

Especially, λ₂−λ₁≥10 nm, more especially, λ₂−λ₁≥15 nm. Hence, in embodiments, the first light generating device and the second light generating device may be from different bins (though other choices may also be possible when selecting different lasers, see also above). In embodiments, the spectral power distributions of the first device light and the second device light overlap less than 25% (i.e. the first spectral power distribution is overlapped by less than 25% by the second spectral power distribution and the second spectral power distribution is overlapped by less than 25% by the first spectral power distribution), such as at maximum 15%. More especially, the spectral power distributions of the first device light and the second device light may overlap less than 10%, such as less than 5%. As the first light generating device and the second light generating device may comprise lasers, and the first device light and the second device light may essentially consist of laser light (with different spectral power distributions) the spectral overlap may even essentially be zero.

In specific embodiments, the first device light peak wavelength (λ₁) may be selected from the wavelength range of 430-460 nm, and/or the second device light peak wavelength (λ₂) may be selected from the wavelength range of 475-485 nm. In specific embodiments, λ₂−λ₁≥20 nm. Further, in specific embodiments, the first centroid wavelength may be selected from the wavelength range of 430-460 nm+/−5 nm, and/or the second centroid wavelength may be selected from the wavelength range of 475-485 nm+/−5 nm, with the centroid wavelengths especially at least differing about 15 nm, such as at least about 20 nm.

The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ)), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions.

Especially, in embodiments in the blue wavelength range of 440-490 nm, there are only two (narrow) emission bands, one provided by the first device light, especially having the first device light peak wavelength (λ₁) selected from the wavelength range of 430-460 nm, and the other one provided by the second device light, especially having the second device light peak wavelength (λ₂) selected from the wavelength range of 475-485 nm. Hence, in specific embodiments, there is no third emission band available in about the range of 460-475. Hence, especially there may be no third peak between the first device light peak wavelength (λ₁) and the second device light peak wavelength (λ₂) (or its maximum is less than 5% of the maximum of the first device peak or of the second device peak.

Here below, first some general aspects in relation to luminescent materials (in general) are discussed.

The term “luminescent material” especially refers to a material that can convert first radiation, especially one or more of UV radiation and blue radiation, into second radiation. In general, the first radiation and second radiation have different spectral power distributions. Hence, instead of the term “luminescent material”, also the terms “luminescent converter” or “converter” may be applied. In general, the second radiation has a spectral power distribution at larger wavelengths than the first radiation, which is the case in the so-called down-conversion. In specific embodiments, however the second radiation has a spectral power distribution with intensity at smaller wavelengths than the first radiation, which is the case in the so-called up-conversion.

In embodiments, the “luminescent material” may especially refer to a material that can convert radiation into e.g. visible and/or infrared light. For instance, in embodiments the luminescent material may be able to convert one or more of UV radiation and blue radiation, into visible light. The luminescent material may in specific embodiments also convert radiation into infrared radiation (IR). Hence, upon excitation with radiation, the luminescent material emits radiation. In general, the luminescent material will be a down converter, i.e. radiation of a smaller wavelength is converted into radiation with a larger wavelength (λₑₓ<λₑₘ), though in specific embodiments the luminescent material may comprise up-converter luminescent material, i.e. radiation of a larger wavelength is converted into radiation with a smaller wavelength (λₑₓ>λₑₘ).

In embodiments, the term “luminescence” may refer to phosphorescence. In embodiments, the term “luminescence” may also refer to fluorescence. Instead of the term “luminescence”, also the term “emission” may be applied. Hence, the terms “first radiation” and “second radiation” may refer to excitation radiation and emission (radiation), respectively. Likewise, the term “luminescent material” may in embodiments refer to phosphorescence and/or fluorescence.

The term “luminescent material” may also refer to a plurality of different luminescent materials. Examples of possible luminescent materials are indicated below.

Hence, the term “luminescent material” may in specific embodiments also refer to a luminescent material composition. Instead of the term “luminescent material” also the term “phosphor” may be applied. These terms are known to the person skilled in the art.

In embodiments, luminescent materials are selected from garnets and nitrides, especially doped with trivalent cerium or divalent europium, respectively. The term “nitride” may also refer to oxynitride or nitridosilicate, etc. Alternatively or additionally, the luminescent material(s) may be selected from silicates, especially doped with divalent europium.

In specific embodiments the luminescent material comprises a luminescent material of the type A₃B₅O₁₂:Ce, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable luminescent materials are cerium comprising garnet materials. Embodiments of garnets especially include A₃B₅O₁₂ garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B may comprise aluminum (Al); however, in addition to aluminum, B may also partly comprise gallium (Ga) and/or scandium (Sc) and/or indium (In), especially up to about 20% of B, more especially up to about 10% of B (i.e. the B ions essentially consist of 90 or more mole % of Al and 10 or less mole % of one or more of Ga, Sc and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y₁₋ₓLuₓ)₃B₅O₁₂:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y₁₋ₓLuₓ)₃Al₅O₁₂:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y_{0.1}Lu_{0.89}Ce_{0.01})₃Al₅O₁₂. Ce in garnets is substantially or only in the trivalent state, as is known to the person skilled in the art.

In embodiments, the luminescent material (thus) comprises A₃B₅O₁₂ wherein in specific embodiments at maximum 10% of B—O may be replaced by Si—N.

In specific embodiments the luminescent material comprises (Yₓ₁A′ₓ₂Ceₓ₃)₃(Al_{y1}B′_{y2})₅O₁₂, wherein x1+x2+x3=1, wherein x3>0, wherein 0<x2+x3≤0.2, wherein y1+y2=1, wherein 0≤y2≤0.2, wherein A′ comprises one or more elements selected from the group consisting of lanthanides, and wherein B′ comprises one or more elements selected from the group consisting of Ga, In and Sc. In embodiments, x3 is selected from the range of 0.001-0.1. In the present invention, especially x1>0, such as >0.2, like at least 0.8. Garnets with Y may provide suitable spectral power distributions.

In specific embodiments at maximum 10% of B—O may be replaced by Si—N. Here, B in B—O refers to one or more of Al, Ga, In and Sc (and O refers to oxygen); in specific embodiments B—O may refer to Al—O. As indicated above, in specific embodiments x3 may be selected from the range of 0.001-0.04. Especially, such luminescent materials may have a suitable spectral distribution (see however below), have a relatively high efficiency, have a relatively high thermal stability, and allow a high CRI (optionally in combination with (the) light of other sources of light as described herein). Hence, in specific embodiments A may be selected from the group consisting of Lu and Gd. Alternatively or additionally, B may comprise Ga. Hence, in embodiments the luminescent material comprises (Yₓ₁(Lu,Gd)ₓ₂Ceₓ₃)₃(Al_{y1}Ga_{y2})₅O₁₂, wherein Lu and/or Gd may be available. Even more especially, x3 is selected from the range of 0.001-0.1, wherein 0<x2+x3≤0.1, and wherein 0≤y2≤0.1. Further, in specific embodiments, at maximum 1% of B—O may be replaced by Si—N. Here, the percentage refers to moles (as known in the art); see e.g. also EP3149108. In yet further specific embodiments, the luminescent material comprises (Yₓ₁₋ₓ₃Ceₓ₃)₃Al₅O₁₂, wherein x1+x3=1, and wherein 0<x3≤0.2, such as 0.001-0.1.

In specific embodiments, the light generating device may only include luminescent materials selected from the type of cerium comprising garnets. In even further specific embodiments, the light generating device includes a single type of luminescent materials, such as (Yₓ₁A′ₓ₂Ceₓ₃)₃(Al_{y1}B′_{y2})₅O₁₂. Hence, in specific embodiments the light generating device comprises luminescent material, wherein at least 85 weight%, even more especially at least about 90 wt. %, such as yet even more especially at least about 95 weight % of the luminescent material comprises (Yₓ₁A′ₓ₂Ceₓ₃)₃(Al_{y1}B′_{y2})₅O₁₂. Here, wherein A′ comprises one or more elements selected from the group consisting of lanthanides, and wherein B′ comprises one or more elements selected from the group consisting of Ga, In and Sc, wherein x1+x2+x3=1, wherein x3>0, wherein 0<x2+x3<0.2, wherein y1+y2=1, wherein 0≤y2≤0.2. Especially, x3 is selected from the range of 0.001-0.1. Note that in embodiments x2=0. Alternatively or additionally, in embodiments y2=0.

In specific embodiments, A may especially comprise at least Y, and B may especially comprise at least Al.

Alternatively or additionally, wherein the luminescent material may comprises a luminescent material of the type A₃Si₆N₁₁:Ce³⁺, wherein A comprises one or more of Y, La, Gd, Tb and Lu, such as in embodiments one or more of La and Y.

In embodiments, the luminescent material may alternatively or additionally comprise one or more of MS:Eu²⁺ and/or M₂Si₅N₈:Eu²⁺ and/or MAlSiN₃:Eu²⁺ and/or Ca₂AlSi₃O₂N₅:Eu²⁺, etc., wherein M comprises one or more of Ba, Sr and Ca, especially in embodiments at least Sr. Hence, in embodiments, the luminescent may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca). Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art.

In embodiments, a red luminescent material may comprise one or more materials selected from the group consisting of (Ba,Sr,Ca)S:Eu, (Ba,Sr,Ca)AlSiN₃:Eu and (Ba,Sr,Ca)₂Si₆N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba.

The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca).

Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Eu in the above indicated luminescent materials is substantially or only in the divalent state, as is known to the person skilled in the art.

Blue luminescent materials may comprise YSO (Y₂SiO₅:Ce³⁺), or similar compounds, or BAM (BaMgAl₁₀O₁₇:Eu²⁺), or similar compounds.

The term “luminescent material” herein especially relates to inorganic luminescent materials.

Alternatively or additionally, also other luminescent materials may be applied. For instance quantum dots and/or organic dyes may be applied and may optionally be embedded in transmissive matrices like e.g. polymers, like PMMA, or polysiloxanes, etc. etc.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention. However, it may be preferred for reasons of environmental safety and concern to use cadmium-free quantum dots or at least quantum dots having a very low cadmium content.

Instead of quantum dots or in addition to quantum dots, also other quantum confinement structures may be used. The term “quantum confinement structures” should, in the context of the present application, be understood as e.g. quantum wells, quantum dots, quantum rods, tripods, tetrapods, or nano-wires, etcetera.

Organic phosphors can be used as well. Examples of suitable organic phosphor materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

Different luminescent materials may have different spectral power distributions of the respective luminescent material light. Alternatively or additionally, such different luminescent materials may especially have different color points (or dominant wavelengths).

As indicated above, other luminescent materials may also be possible. Hence, in specific embodiments the luminescent material is selected from the group of divalent europium containing nitrides, divalent europium containing oxynitrides, divalent europium containing silicates, cerium comprising garnets, and quantum structures. Quantum structures may e.g. comprise quantum dots or quantum rods (or other quantum type particles) (see above). Quantum structures may also comprise quantum wells. Quantum structures may also comprise photonic crystals.

As indicated above, in embodiments the first luminescent material is configured in a light receiving relationship with the first light generating device. Hence, the first luminescent material may be configured downstream of the first light generating device.

The terms “light-receiving relationship” or “light receiving relationship”, and similar terms, may indicate that an item may during operation of a source of light (like a light generating device or light generating element or light generating system) may receive light from that source of light. Hence, the item may be configured downstream of that source of light. Between the source of light and the item, optics may be configured. The terms “upstream” and “downstream”, such as in the context of propagation of light, may especially relate to an arrangement of items or features relative to the propagation of the light from a light generating element (here the especially the first light generating device), wherein relative to a first position within a beam of light from the light generating element, a second position in the beam of light closer to the light generating element (than the first position) is “upstream”, and a third position within the beam of light further away from the light generating element (than the first position) is “downstream”. For instance, instead of the term “light generating element” also the term “light generating means” may be applied.

Further, the first luminescent material is configured to convert at least part of the first device light (received from the first light generating device) into first luminescent material light. Especially, the spectral power distribution of the first luminescent material, upon excitation by the first device light, may show intensity at least within the green-yellow wavelength range. Hence, the first luminescent material light may have intensity in the wavelength range of 490-590 nm. More especially, the first luminescent material light may have a luminescent material emission centroid wavelength (λ_{c,1}) within the green-yellow wavelength range, i.e. within the wavelength range of 490-590 nm.

The terms “violet light” or “violet emission”, and similar terms, may especially relate to light having a wavelength in the range of about 380-440 nm. In specific embodiments, the violet light may have a centroid wavelength in the 380-440 nm range. The terms “blue light” or “blue emission”, and similar terms, may especially relate to light having a wavelength in the range of about 440-490 nm (including some violet and cyan hues). In specific embodiments, the blue light may have a centroid wavelength in the 440-490 nm range. The terms “green light” or “green emission”, and similar terms, may especially relate to light having a wavelength in the range of about 490-560 nm. In specific embodiments, the green light may have a centroid wavelength in the 490-560 nm range. The terms “yellow light” or “yellow emission”, and similar terms, may especially relate to light having a wavelength in the range of about 560-590 nm. In specific embodiments, the yellow light may have a centroid wavelength in the 560-590 nm range. The terms “orange light” or “orange emission”, and similar terms, may especially relate to light having a wavelength in the range of about 590-620 nm. In specific embodiments, the orange light may have a centroid wavelength in the 590-620 nm range. The terms “red light” or “red emission”, and similar terms, may especially relate to light having a wavelength in the range of about 620-750 nm. In specific embodiments, the red light may have a centroid wavelength in the 620-750 nm range. The terms “cyan light” or “cyan emission”, and similar terms, especially relate to light having a wavelength in the range of about 490-520 nm. In specific embodiments, the cyan light may have a centroid wavelength in the 490-520 nm range. The terms “amber light” or “amber emission”, and similar terms, may especially relate to light having a wavelength in the range of about 585-605 nm, such as about 590-600 nm. In specific embodiments, the amber light may have a centroid wavelength in the 585-605 nm range. The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range.

The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light.

Therefore, in embodiments the first luminescent material is configured in a light receiving relationship with the first light generating device and is configured to convert at least part of the first device light into first luminescent material light having a luminescent material emission centroid wavelength (λ_{c,1}) within the green-yellow wavelength range. Especially, however, the first luminescent material may not be configured in a light receiving relationship with the second light generating device. Hence, the first light generating device, the second light generating device, and the first luminescent material (and optional optics) may be configured such that at least part of the first device light reaches the first luminescent material, whereas essentially no second device light reaches the first luminescent material.

Hence, especially the second device light may bypass the first luminescent material. In this way, the second device light may not be absorbed by the first luminescent material, while the first luminescent material might in principle absorb at least part of the second device light, would such second device light reach the first luminescent material. Hence, the first luminescent material may be able to absorb (and convert) at least part of the first device light, and the first luminescent material may also be able to absorb (and convert) at least part of the second device light, but may be configured such, that essentially no second device light reaches the first luminescent material.

Light may bypass the luminescent material when it is not irradiating (in transmissive or reflective mode) the luminescent material. When the light bypasses the luminescent material, it will also not be converted by the luminescent material. Hence, in embodiments the second device light is (essentially) not converted by the first luminescent material (as the second device light may bypass the first luminescent material).

As indicated above, the light generating system may be configured to generate system light comprising one or more of the first device light, the second device light, and the first luminescent material light. In specific embodiments, in an operational mode of the system, the system light may comprise all of the first device light, the second device light, and the first luminescent material light.

In embodiments, the light generating system may be configured to generate visible light (in one or more operational modes of the light generating system). In further specific embodiments, the light generating system may be configured to generate white light (in one or more operational modes of the light generating system).

The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm. The term “white light”, and similar terms, herein, is known to the person skilled in the art. It may especially relate to light having a correlated color temperature (CCT) between about 1800 K and 20000 K, such as between 2000 and 20000 K, especially 2700-20000 K, for general lighting especially in the range of about 2000-7000 K, such as in the range of 2700 K and 6500 K. In embodiments, e.g. for backlighting purposes, or for other purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL. In specific embodiments, the correlated color temperature (CCT) may be selected from the range of 6000-12000 K, like selected from the range of 7000-12000 K, like at least 8000 K. Yet further, in embodiments the correlated color temperature (CCT) may be selected from the range of 6000-12000 K, like selected from the range of 7000-12000 K, optionally in combination with a CRI of at least 70.

In specific embodiments, the system light may have a controllable correlated color temperature. Especially, a spectral power distribution of the system light may be controlled by controlling the first device light and the second device light. Therefore, in embodiments the control system is configured to control the first light generating device and the second light generating device.

Especially, the control system may be configured to control the first light generating device and the second light generating device, such that (a) in a first operational mode of the light generating system the system light has a first correlated color temperature CCT1, wherein CCT1≥4000 K. This does not necessarily exclude operational modes wherein the first correlated color temperature is below 4000 K.

Yet, alternatively or additionally, the control system may be configured to control the first light generating device and the second light generating device, such that (b) in a second operational mode of the light generating system the system light has a second correlated color temperature (CCT2), wherein in embodiments CCT2−CCT1≥500 K, more especially CCT2−CCT1≥1000 K, or even a larger (minimum) difference. Again, this does not necessarily exclude operational modes wherein CCT2−CCT1≤500 K or wherein CCT2−CCT1≤1000 K.

Yet, alternatively or additionally, the control system may be configured to control the first light generating device and the second light generating device, such that (c) in at least one of the operational modes, the system light has a correlated color temperature selected from the range of at least 6000 K, more especially at least 7000 K. Again, this does not necessarily exclude operational modes wherein both the correlated color temperatures are below 7000 K, or below 6000 K. Further, this may also include embodiments comprising one or more operational modes wherein at one of the correlated color temperatures is below 6000 K, and the other one is above 6000 K, or one of the correlated color temperatures is below 7000 K, and the other one is above 7000 K, especially embodiments wherein, as indicated above, the CCT difference is at least 1000 K. Further, alternatively or additionally, the control system may be configured to control the first light generating device and the second light generating device, such that (d) the system light in both operational modes has a color rendering index of at least 70. Again, this does not necessarily exclude operational modes wherein one or both the first and second operational mode the CRI is below 70.

In specific embodiments, the CCT (of the white system light) may be controlled between a first value (CCT1) and a second value (CCT2), wherein |CCT2−CCT1|≥500 K, more especially |CCT2−CCT1|≥1000 K. In specific embodiments, |CCT2−CCT1|≥1500 K, such as |CCT2−CCT1|≥1800 K, like more especially |CCT2−CCT1|≥2000 K. Especially, in embodiments |CCT2−CCT1|23000 K, such as in the case wherein the correlated color temperature maybe selected from the range of 7000-10000 K. In embodiments, the CRI over the entire 7000-10000 K range may be at least 70, more especially at least 80, such as at least 85. In yet further embodiments, the CRI over the entire 7000-10000 K range may be at least 90.

As indicated above, the system may comprise a control system, or may be functionally coupled to a control system. The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions from a remote control. In embodiments, the control system may be controlled via an App on a device, such as a portable device, like a Smartphone or I-phone, a tablet, etc. The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, Thread, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, which can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

When controlling the CCT, especially at relatively high correlated color temperatures, the color point may stay relatively close to the black body locus, such as within 10 SDCM, more especially within 5 SDCM, or even within about 3 SDCM from the BBL.

Relative to the first light generating device, the first luminescent material may be configured in the reflective mode or the transmissive mode.

Further, the system may comprise a first optical element configured to focus the first device light on at least part of the first luminescent material. Such first optical element may comprise a lens. In embodiments, the first optical element may comprise one or two lenses to focus the first device light on at least part of the first luminescent material. When a plurality of first light generating devices is applied, e.g. a lens array may be applied. However, in (other) embodiments the first optical element may also comprise a collimator. Would in such embodiments a plurality of first light generating devices is applied, e.g. a collimator array may be applied. Such arrays may be comprised by a body (like e.g. a (micro) lens plate). Embodiments are e.g. also described in US2005/0270775, which is herein incorporated by reference.

Hence, in embodiments the first luminescent material is configured in the reflective mode; and the light generating system comprises a first optical element configured to focus the first device light on at least part of the first luminescent material. In alternative embodiments, the first luminescent material may be configured in the transmissive mode; and the light generating system comprises a first optical element configured to focus the first device light on at least part of the first luminescent material.

As indicated above, the (first) luminescent material may be configured in the reflective mode or in the transmissive mode. In the transmissive mode, it may be relatively easy to have light source light admixed in the luminescent material light, which may be useful for generating the desirable spectral power distribution. In the reflective mode, thermal management may be easier, as a substantial part of the luminescent material may be in thermal contact with a thermally conductive element, like a heatsink or heat spreader. In the reflective mode, a part of the light source light may in embodiments be reflected by the luminescent material and/or a reflector and may be admixed in the luminescent material light. The reflector may be configured downstream of the luminescent material (in the reflective mode). In the reflective mode, a dichroic reflector may be used, to promote the luminescent material light over the device light. The former may be transmitted with a higher transmission than the latter and the latter may be reflected with a higher reflection than the former.

When pump light may have a spectral power distribution that may be used for both pumping the luminescent material and admixing in the system light, several options may be chosen. In embodiments, a plurality of first light generating devices may be applied, wherein one or more are used to pump the luminescent material, and one or more other first light generating devices are configured to provide first device light that bypasses the luminescent material. Alternatively or additionally, one or more first light generating devices may be used to generate first device light of which part is directed to the luminescent element and of which another part may be configured to bypass the luminescent element. This may be done e.g. via a beam splitter. Light may bypass the luminescent element when it is not irradiating (in transmissive or reflective mode) the luminescent element.

Therefore, it may be useful that part of the first device light also ends up in the system light. This may be achieved by one or more of (i) only partial absorption (and thus partial reflection and/or transmission), and (ii) bypassing with part of the first device light the first luminescent material. Light that bypasses or is not converted by the (first) luminescent material after reaching the (first) luminescent material may be indicated as “unconverted first device light”, and similar terms.

Hence, in embodiments, the first light generating device and the first luminescent material may be configured such that part of the first device light is converted into the luminescent material light. Therefore, in specific embodiments the system light may comprise (i) at least part of (the) non-converted first device light and (ii) the first luminescent material light. More especially, in embodiments the system light may comprise (i) at least part of the non-converted first device light, (ii) the second device light, and (iii) the first luminescent material light.

Hence, in (other) embodiments the system may comprise one or more first light generating devices configured to generate the first device light, wherein the one or more first light generating devices and optional optics are configured such that part of the first device light bypasses the first luminescent material. Therefore, in specific embodiments the system light may comprise (i) at least part of the non-converted first device light and (ii) the first luminescent material light. More especially, in embodiments the system light may comprise (i) at least part of the non-converted first device light, (ii) the second device light, and (iii) the first luminescent material light.

Bypassing may be obtained by splitting a beam of first device light into two or more beams, one propagating to the first luminescent material and the other one bypassing the first luminescent material, and/or by using two or more first light generating devices, wherein first device light of one first light generating devices is propagating to the first luminescent material and first device light of another first light generating device is bypassing the first luminescent material. The system comprises a plurality of first light generating devices, wherein the plurality of first light generating devices comprises a primary first light generating device and a secondary first light generating device, wherein the first luminescent material is configured in a light receiving relationship with one of the primary first light generating device and the secondary first light generating device, and wherein the first luminescent material is not configured in a light receiving relationship with the other one of the primary first light generating device and the secondary first light generating device.

In embodiments, the first luminescent material may be configured in thermal contact with a thermally conductive body. Further, in embodiments the first luminescent material may be comprised by a luminescent body. In specific embodiments, the luminescent body may be configured in thermal contact with a thermally conductive body.

The thermally conductive body may comprise a thermally conductive material. A thermally conductive element may especially comprise a thermally conductive material. A thermally conductive material may especially have a thermal conductivity of at least about 20 W/(m*K), like at least about 30 W/(m*K), such as at least about 100 W/(m*K), like especially at least about 200 W/(m*K). In yet further specific embodiments, a thermally conductive material may especially have a thermal conductivity of at least about 10 W/(m*K). In embodiments, the thermally conductive material may comprise one or more of copper, aluminum, silver, gold, silicon carbide, aluminum nitride, boron nitride, aluminum silicon carbide, beryllium oxide, a silicon carbide composite, aluminum silicon carbide, a copper tungsten alloy, a copper molybdenum carbide, carbon, diamond, and graphite. Alternatively, or additionally, the thermally conductive material may comprise or consist of aluminum oxide.

The thermally conductive body may comprise a heatsink or heat spreader. The thermally conductive body may comprise a two-phase cooling device. Heatsinks are known in the art. The term “heatsink” (or heat sink) may especially be a passive heat exchanger that transfers the heat generated by device, such as an electronic device or a mechanical device, to a fluid (cooling) medium, often air or a liquid coolant. Thereby, the heat is (at least partially) dissipated away from the device. A heat sink is especially designed to maximize its surface area in contact with the fluid cooling medium surrounding it. Hence, especially a heatsink may comprise a plurality of fins. For instance, the heatsink may be a body with a plurality of fins extending thereof. A heatsink especially comprises (more especially consists of) a thermally conductive material. The term “heatsink” may also refer to a plurality of (different) heatsinks. A heat spreader may be configured to transfer energy as heat from a first element to a second element. The second element may especially be a heatsink or heat exchanger. A heat spreader may passive or active. Embodiments of passive heat spreaders may comprise a plate or block of material having high thermal conductivity, such as copper, aluminum, or diamond. An active heat spreader may be configured to speed up heat transfer with expenditure of energy as work supplied by an external source. Herein, the heat spreader may especially be a passive heat spreader. Alternatively or additionally, the heat spreader may be an active heat spreader, such as selected from the group of heat pipes and vapor chambers. A heat spreader especially comprises (more especially consists of) a thermally conductive material. The term “heat spreader” may also refer to a plurality of (different) heat spreaders. Two-phase cooling devices may be devices that transfer heat between two locations based on both thermal conductivity and phase transition. In particular, liquid, such as water (e.g. for a copper device) or acetone (e.g. for an aluminum device), may be added to the two-phase cooling device and the two-phase cooling device may be vacuum sealed. When heat is applied to one area of the two-phase cooling device, the liquid may turn to vapor and move to an area of lower pressure where it cools and returns to liquid form whereupon it moves back to the heat source. In embodiments, the two-phase cooling device may especially comprise a heat pipe or a vapor chamber element, especially a heat pipe, or especially a vapor chamber element. Vapor chamber elements and heat pipes are known in the art and may be based on essentially the same principle. A difference between the heat pipe and the vapor chamber element may be that the heat pipe may typically have an essentially rod-shaped shape, whereas the vapor chamber element may in general have a planar shape. In particular, the vapor chamber element may include two essentially planar plates at a relative short distance (such as up to 5 mm). Further, for the vapor chamber element the hot spot may relatively freely be chosen, whereas for a heat pipe there is generally a hot and cold side at the opposing sides of the rod, such as at the bases of a cylinder-shaped heat pipe.

An element may be considered in “thermal contact” with another element if it can exchange energy through the process of heat. Hence, the elements may be thermally coupled. In embodiments, thermal contact can be achieved by physical contact. In embodiments, thermal contact may be achieved via a thermally conductive material, such as a thermally conductive glue (or thermally conductive adhesive). Thermal contact may also be achieved between two elements when the two elements are arranged relative to each other at a distance of equal to or less than about 10 μm, though larger distances, such as up to 100 μm may be possible. The shorter the distance, the better the thermal contact. Especially, the distance is 10 μm or less, such as 5 μm or less, such as 1 μm or less. The distance may be the distanced between two respective surfaces of the respective elements. The distance may be an average distance. For instance, the two elements may be in physical contact at one or more, such as a plurality of positions, but at one or more, especially a plurality of other positions, the elements are not in physical contact. For instance, this may be the case when one or both elements have a rough surface. Hence, in embodiments in average the distance between the two elements may be 10 μm or less (though larger average distances may be possible, such as up to 100 μm). In embodiments, the two surfaces of the two elements may be kept at a distance with one or more distance holders. When two elements are in thermal contact, they may be in physical contact or may be configured at a short distance of each other, like at maximum 10 μm, such as at maximum 1 mm. When the two elements are configured at a distance from each other, an intermediate material may be configured in between, though in other embodiments, the distance between the two elements may filled with a gas, liquid, or may be vacuum. When an intermediate material is available, the larger the distance, the higher the thermal conductivity may be useful for thermal contact between the two elements. However, the smaller the distance, the lower the thermal conductivity of the intermediate material may be (of course, higher thermal conductive materials may also be used).

The luminescent body may be a layer, like a self-supporting layer. The luminescent body may also be a coating. The luminescent body may also comprise a luminescent coating on a support (especially a light transmissive support in the transmissive mode, or a reflective support in the reflective mode). Especially, the luminescent body may essentially be self-supporting. In embodiments, the luminescent material may be provided as luminescent body, such as a luminescent single crystal, a luminescent glass, or a luminescent ceramic body. Such body may be indicated as “converter body” or “luminescent body”. In embodiments, the luminescent body may be a luminescent single crystal or a luminescent ceramic body. For instance, in embodiments a cerium comprising garnet luminescent material may be provided as a luminescent single crystal or as a luminescent ceramic body. In other embodiments, the luminescent body may comprise a light transmissive body, wherein the luminescent material is embedded. For instance, the luminescent body may comprise a glass body, with luminescent material embedded therein. Or, the glass as such may be luminescent. In other embodiments, the luminescent body may comprise a polymeric body, with luminescent material embedded therein. The luminescent body may have any shape. In general, however, the luminescent body may comprise two essentially parallel faces, defining a height (of the luminescent body). Further, the luminescent body may comprise an edge face, bridging the two essentially parallel faces. The edge face may be curved in one or two dimensions. The edge face may be planar. The luminescent body may have a rectangular or circular cross-section, though other cross-sections may also be possible, like e.g. hexagonal, octagonal, etc. Hence, the luminescent body may have a circular cross-section, an oval cross-section, square, or non-square rectangular. In embodiments, the luminescent body may have an n-gonal cross-section, wherein n is at least 3, like 4 (square or rectangular cross-section), 5 (pentagonal cross-section), 6 (hexagonal cross-section), 8 (octagonal cross-section) or higher. The two essentially parallel faces may also be indicated as “main faces”, as they may especially provide the largest external area of the luminescent body. Perpendicular to the afore-mentioned cross-section, may be another cross-section, which may in embodiments be rectangular. Hence, the luminescent body may e.g. have a cubic shape, a (non-cubic) cuboid shape, an n-gonal prism shape with n being at least 5 (such as pentagonal prism, hexagonal prism), and a cylindrical shape. Other shapes, however, may also be possible. Especially, the luminescent body may have a cuboid shape, a cylindrical shape, or an n-gonal prism shape wherein n is 6 or 8.

In embodiments, the luminescent body (or “body”) has lateral dimensions width or length (W1 or L1) or diameter (D) and a thickness or height (H1). In embodiments, (i) D≥H1 or (ii) and W1≥H1 and/or L1≥H1. The luminescent body may be transparent or light scattering. In embodiments, the luminescent body may comprise a ceramic luminescent material. In specific embodiments, L1≤10 mm, such as especially L1≤5 mm, more especially L1≤3 mm, most especially L1≤2 mm. In specific embodiments, W1≤10 mm, such as especially W1≤5 mm, more especially W1≤3 mm, most especially W1≤2 mm. In specific embodiments, H1≤10 mm, such as especially H1≤5 mm, more especially H1≤3 mm, most especially H1≤2 mm. In specific embodiments, D≤10 mm, such as especially D≤5 mm, more especially D≤3 mm, most especially D≤2 mm. In specific embodiments, the body may have in embodiments a thickness in the range 50 μm-1 mm. Further, the body may have lateral dimensions (width/diameter) in the range 100 μm-10 mm. In yet further specific embodiments, (i) D>H1 or (ii) W1>H1 and L1>H1. Especially, the lateral dimensions like length, width, and diameter are at least 2 times, like at least 5 times, larger than the height. In specific embodiments, the luminescent body has a first length L1, a first height H1, and a first width W1, wherein H1≤0.5*L1 and H1≤0.5*W1. In embodiments, the luminescent body may be a (small) tile. In embodiments, the luminescent body may comprises a first face, a second face, and a side face bridging the first face and the second face). The first face and the second face may also be indicated as main faces. In the case of a cylindrical shape, the side face may be a single side face. In the case of a cuboid, the side face may comprise four facets. In the case of a hexagonal prism the side face may comprise six facets.

Hence, in embodiments the system may comprise (i) a luminescent body comprising the first luminescent material, (ii) a first thermally conductive body configured in thermal contact with the first luminescent material (more especially, in embodiments the first thermally conductive body may be configured in thermal contact with the luminescent body).

The thermally conductive body may be used to cool the (first) luminescent material, which may be subjected to relatively intense laser light. Alternatively or additionally, an (other) thermally conductive body may be used to cool the first light generating device and/or the second light generating device. In embodiments, the system may comprise a laser bank, comprising a plurality of first laser light sources. Alternatively or additionally, the system may comprise a laser bank, comprising a plurality of second laser light sources. The laser bank(s) may be configured in thermal contact with one or more thermally conductive bodies. In specific embodiments, the system may (further) comprise (i) a laser bank comprising the first laser light source, the second laser light source, and (ii) a second thermally conductive body configured in thermal contact with the first laser light source and the second laser light source. The phrase “a laser bank comprising a laser light source”, and similar phrases, may also be interpreted as a laser bank hosting a laser light source. Laser banks are known in the art and may also be indicated as “laser array banks”.

A good (first) luminescent material may be a garnet type luminescent material, doped with cerium. Such materials are known in the art. In specific embodiments, the first luminescent material comprises a luminescent material of the type A₃B₅O₁₂:Ce, wherein A comprises one or more of Y, La, Gd, Tb and Lu, and wherein B comprises one or more of Al, Ga, In and Sc. As indicated above, the system may comprise a luminescent body comprising the first luminescent material. Especially, in embodiments the luminescent body may comprise a ceramic body (especially comprising the luminescent material of the type A₃B₅O₁₂:Ce³⁺).

In order to increase the color rendering index and/or to increase the CCT range and/or to increase the color gamut of the system light, one or more of a second luminescent material and a third light generating device may be applied, which may be configured to generate (luminescent material) light in the yellow and/or orange and/or red wavelength range(s), especially in the orange-red wavelength range. Especially, such second luminescent material may be configured to convert (also) part of the first device light, though other solutions may also be possible. Therefore, in embodiments the system may further comprise one or more of: (a) a second luminescent material configured to convert at least part of the first device light into second luminescent material light having a second centroid wavelength (λ_{c,2}), especially in the yellow-red wavelength range; and (b) a third light generating device comprising a third laser light source and configured to generate third device light having a third device light peak wavelength (λ3) and having a third spectral power distribution, different from the first spectral power distribution and different from the second spectral power distribution; wherein the third device light peak wavelength (λ3) may be selected from the yellow-red wavelength range, especially from the orange-red wavelength range, more especially from the wavelength range of 600-650 nm. The term “yellow-red wavelength range” may especially refer to the wavelength range of 560-780 nm. The term “orange-red wavelength range” may especially refer to the wavelength range of 590-780 nm. In specific embodiments, λ_{c,1}<λ_{c,2}. For instance, in embodiments λ_{c,2}−λ_{c,1}≥15 nm, such as λ_{c,2}−λ_{c,1}≥20 nm, more especially λ_{c,2}−λ_{c,1}≥30 nm.

Note that the term “third light generating device” may also refer to a plurality of (different) third light generating device. Likewise, this may apply to the terms “first light generating device” and “second light generating device”, respectively. Further, the term “second luminescent material” may also refer to a plurality of different second luminescent materials.

As indicated above, in embodiments the system may comprise a luminescent body, comprising the first luminescent material. In specific embodiments, wherein the system also comprises a second luminescent material, the luminescent body may (also) comprise the second luminescent material.

As indicated above, in embodiments the second device light is (essentially) not converted by the first luminescent material (as the second device light may bypass the first luminescent material). Further, in embodiments the second device light is (essentially) not converted by the second luminescent material (as the second device light may bypass the second luminescent material).

As indicated above, the first luminescent material may not be configured downstream of the second light generating device. As the second device light as well as the first luminescent material light may be comprised by the system light (in one or more operation modes of the system), the two types of light may have to be combined. Therefore, in embodiments the system may further comprise a beam combiner configured to combine at least part of the first device light and at least part of the second device light into a beam of device light. Especially, in embodiments the beam combiner may be selected from the group of a dichroic beam combiner and a polarizing beam combiner. In embodiments, light mixing optics may (thus) be applied to combine light from different sources and/or light propagating via different optical pathways. In embodiments, the light mixing optics may comprise one or more of diffusers (surface or volume scattering diffusers or engineered holographic optical elements), light pipes, light guides, Koehler integrator optics, etc. Alternatively or additionally, the light mixing optics may comprise a collimator or other collimating optics. Alternatively or additionally, the light mixing optics may comprise a dichroic beam combiner, such as in specific embodiments a dichroic cube. In embodiments, the light mixing optics may comprise a dichroic beam splitter.

It may be desirable, to generate a beam of system light which may be relatively collimated. To this end, e.g. second optics may be applied. Such second optics may comprise one or more of a collimator and a lens. Such second optics may be configured downstream of the first luminescent material, the first light generating device, the second light generating device, the optional second luminescent material and the optional third light generating device. In embodiments, the second optical element may comprise one or more lenses to collimate the system light. When a plurality of first light generating devices is applied, e.g. a lens array may be applied. Alternatively, a collimator, or array of collimators, respectively, may be applied. Embodiments are e.g. also described in US2005/0270775, which is herein incorporated by reference.

Hence, in embodiments the system may further comprise second optics configured to beam shape the system light into a beam (of system light) having a full width half maximum of at maximum 5°, more especially at maximum 3°, yet even more especially at maximum 2°, such as at maximum about 1.5°.

As indicated above, it may be desirable to control a correlated color temperature of the system light. In specific embodiments, the control system may be configured to control the first light generating device and the second light generating device (and the optional third light generating device), such that in a (third) operational mode of the light generating system the system light has a correlated color temperature selected from the range of at least 6000 K, like at least 6500 K, such as selected from the range of 7000-10000 K. In specific embodiments, the system light may have a correlated color temperature selected from the range of at least 7500 K, such as at least about 7800 K. Yet, in specific embodiments the system light may have a correlated color temperature selected from the range of at least 8000 K. In embodiments, such (third) operational mode may comprise the second operational mode as described herein, though in other embodiments it may also comprise the first operational mode. Especially, the first operational mode and the second operational mode are not temporarily overlapping.

In embodiments, in one of the operational modes of the light generating system the system light may have a spectral power distribution in the visible wavelength range wherein at least 5% of the spectral power is provided by the second device light; wherein at least 25% of the spectral power distribution is provided by the first device light, and wherein at least 30% of the spectral power distribution is provided by the first luminescent material light. Additionally or alternatively, in (another) one of the operational modes of the light generating system the system light may have a spectral power distribution in the visible wavelength range wherein less than 1% of the spectral power is provided by the second device light; wherein at least 25% of the spectral power distribution is provided by the first device light, and wherein at least 30% of the spectral power distribution is provided by the first luminescent material light.

In embodiments, in an operational mode the control system may control the system light such that when increasing the correlated color temperature, a radiant flux of the system light is increased, and that when decreasing the correlated color temperature, a radiant flux of the system light is decreased. This may also be indicated as “BBL dimming”.

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

In yet a further aspect, the invention also provides a lamp or a luminaire comprising the light generating system as defined herein. The luminaire may further comprise a housing, optical elements, louvres, etc. etc. The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a light generating device selected from the group of a lamp, a luminaire, a projector device, a disinfection device, a photochemical reactor, and an optical wireless communication device, comprising the light generating system as defined herein. The light generating device may comprise a housing or a carrier, configured to house or support, one or more elements of the light generating system. For instance, in embodiments the light generating device may comprise a housing or a carrier, configured to house or support one or more of the first light generating device, the second light generating device, the first luminescent material, and optional other components, such as mentioned above.

Especially, the lamp or luminaire may be configured for stage lighting. Hence, in an aspect the invention also provides a method for providing light to a stage, comprising generating system light with the light generating system as described herein, in a space comprising a stage. The stage can be indoors, like a theater, but the stage can also be outdoors, like in a stadium or a stage at a festival, TV studio lighting, etc.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depict some embodiments;

FIGS. 2a-2b schematically depict some aspects; and

FIG. 3 schematically depict some application embodiments. The schematic drawings are not necessarily to scale.

### DETAILED DESCRIPTION OF THE EMBODIMENTS

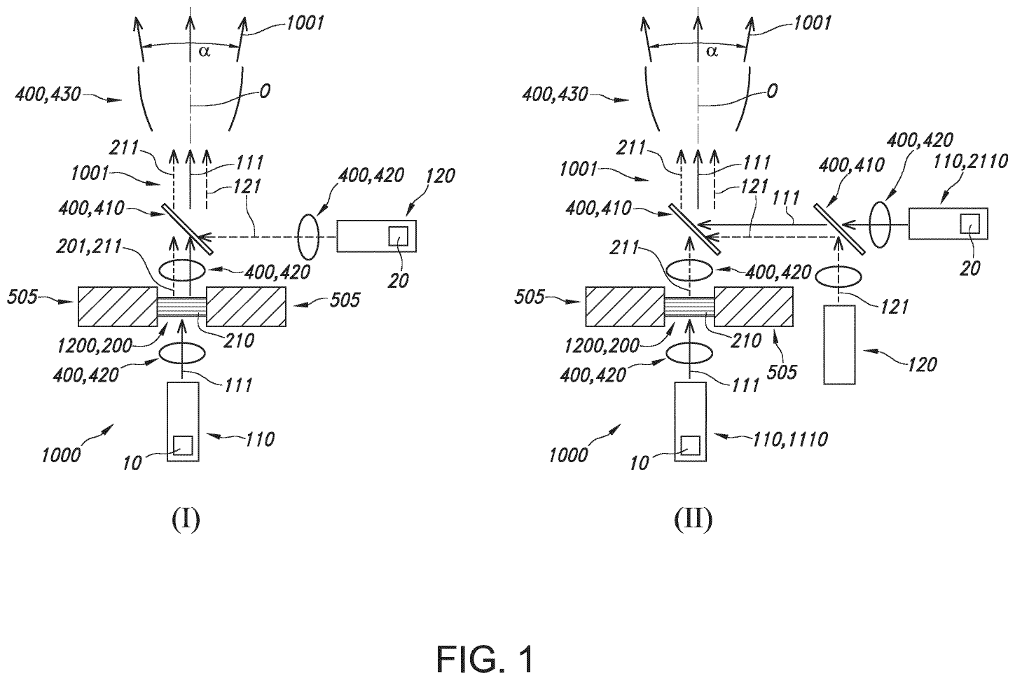

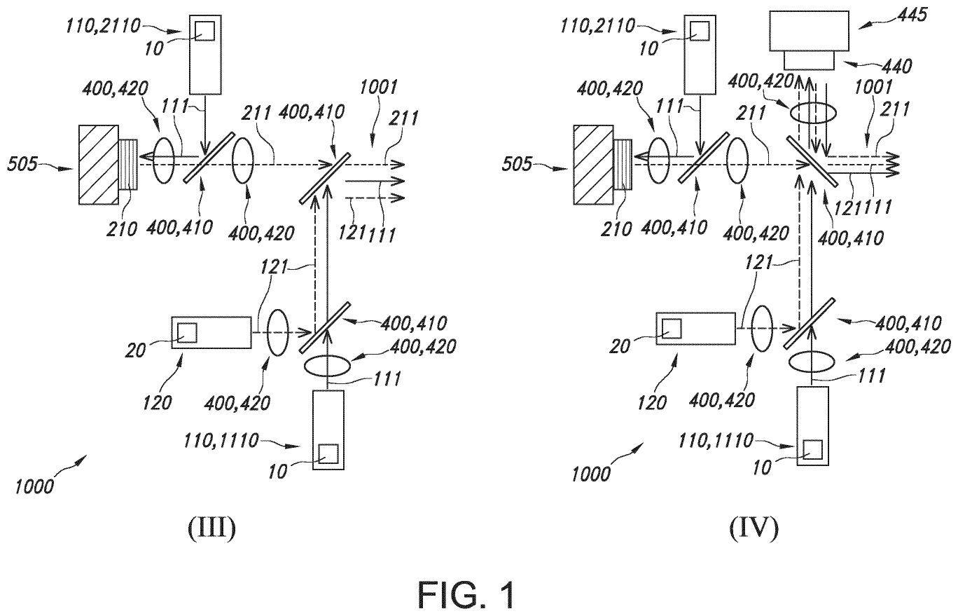

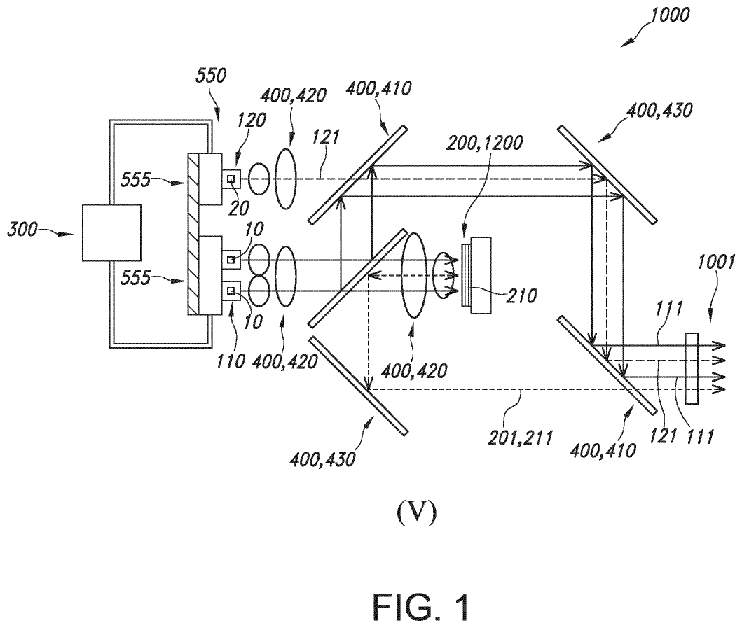

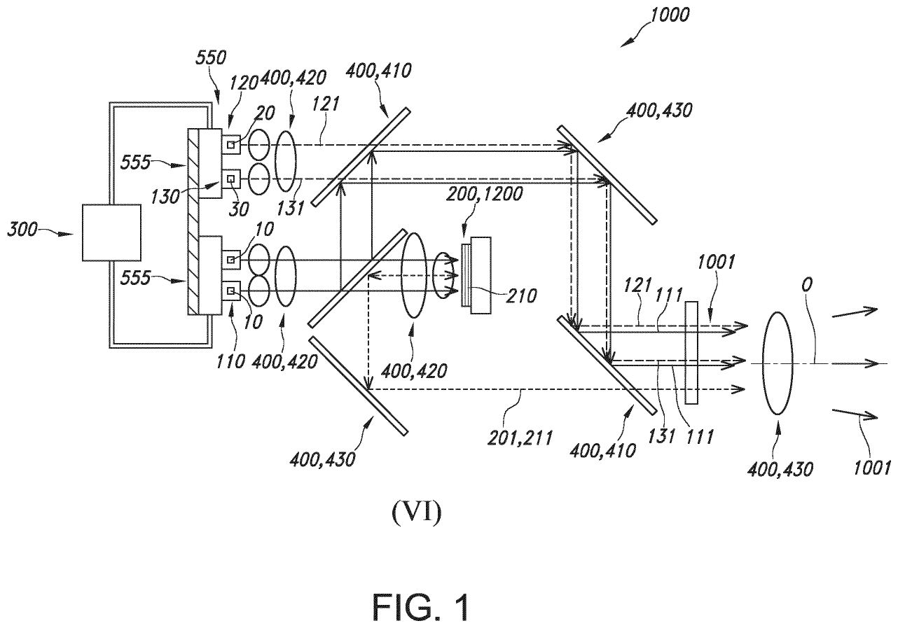

FIG. 1 schematically depicts six possible embodiments. Referring to these embodiments, a light generating system 1000 comprising a first light generating device 110, a second light generating device 120, and a first luminescent material 210 are depicted. Further, a control system 300, may be available; however not drawn in all embodiments.

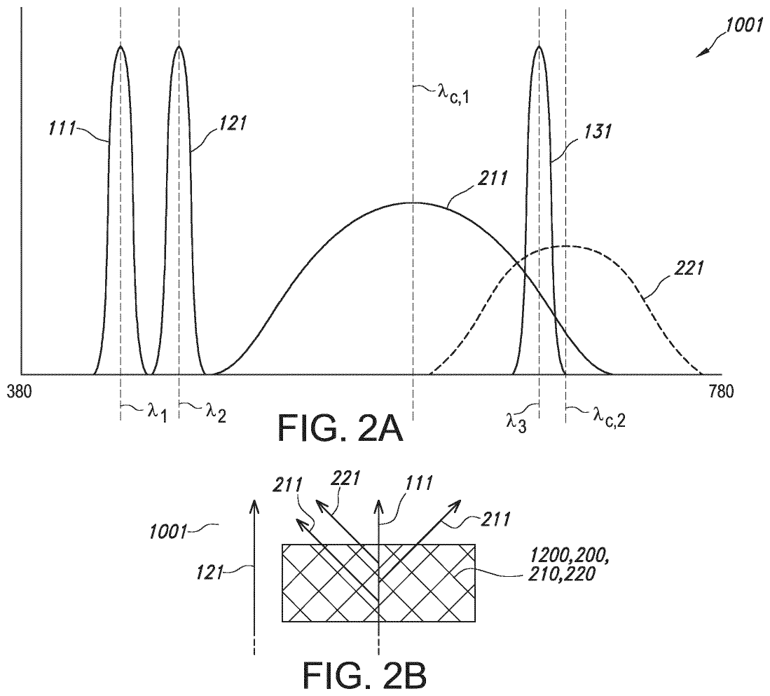

The first light generating device 110 may comprise a first laser light source 10 and may be configured to generate first device light 111 having a first device light peak wavelength 21 and having a first spectral power distribution (see also FIG. 2a). The first device light peak wavelength 21 may be selected from the wavelength range of 425-465 nm. The second light generating device 120 may comprise a second laser light source 20 and may be configured to generate second device light 121 having a second device light peak wavelength 22 and having a second spectral power distribution, different from the first spectral power distribution (see also FIG. 2a). The second device light peak wavelength (λ₂) may be selected from the range of 470-490 nm. The first luminescent material 210 may be configured in a light receiving relationship with the first light generating device 110 and may be configured to convert at least part of the first device light 111 into first luminescent material light 211 having a luminescent material emission centroid wavelength λ_{c,1} within the green-yellow wavelength range (see also FIG. 2a). The first luminescent material 210 may be not configured in a light receiving relationship with the second light generating device 120. Especially, the light generating system 1000 may be configured to generate system light 1001 comprising one or more of the first device light 111, the second device light 121, and the first luminescent material light 211. The system light 1001 has a controllable correlated color temperature. A control system, indicated with reference 300 (see e.g. embodiments V-VI; but such control system 300 may of course also be available in the schematically depicted embodiments I-IV) may be configured to control the first light generating device 110 and the second light generating device 120, such that one or more of the following may apply: (a) in a first operational mode of the light generating system 1000 the system light 1001 has a first correlated color temperature CCT1, wherein CCT1≥4000 K, (b) in a second operational mode of the light generating system 1000 the system light 1001 has a second correlated color temperature (CCT2), wherein CCT2−CCT1≥1000 K, (c) in at least one of the operational modes, the system light 1001 has a correlated color temperature selected from the range of at least 7000K, and (d) the system light 1001 in both operational modes has a color rendering index of at least 70.

In embodiments, the first light generating device 110 and the first luminescent material 210 may be configured such that part of the first device light 111 may be converted into the luminescent material light 211. In embodiments, the system light 1001 may comprise (i) at least part of (the) non-converted first device light 111, (ii) the second device light 121, and (iii) the first luminescent material light 211.

In embodiments, see e.g. embodiments II-VI, the light generating system 1000 may comprise one or more first light generating devices 110 configured to generate the first device light 111. The one or more first light generating devices 110 and optional optics 400 may be configured such that part of the first device light 111 bypasses the first luminescent material 210. In embodiments, the system light 1001 may comprise (i) at least part of (the) first device light 111 bypassing the first luminescent material 210, (ii) the second device light 121, and (iii) the first luminescent material light 211. Hence, in embodiments the light generating system 1000 may comprise a plurality of first light generating devices 110. The plurality of first light generating devices 110 may comprise a primary first light generating device 1110 and a secondary first light generating device 2110. The first luminescent material 210 may be configured in a light receiving relationship with one of the primary first light generating device 1110 and the secondary first light generating device 2110, and the first luminescent material may be not configured in a light receiving relationship with the other one of the primary first light generating device 1110 and the secondary first light generating device 2110.

In embodiments, the light generating system 1000 may comprise a luminescent body 1200 comprising the first luminescent material 210. Alternatively or additionally, in embodiments, the light generating system 1000 may comprise a first thermally conductive body 505 configured in thermal contact with the first luminescent material 210. Especially, in embodiments the first thermally conductive body 505 may be configured in thermal contact with the luminescent body 1200. Further, in embodiments the light generating system 1000 may comprise a laser bank 550 comprising the first laser light source 10, the second laser light source 20, and a second thermally conductive body 555 configured in thermal contact with the first laser light source 10 and the second laser light source 20 (see the schematically depicted embodiments V-VI).

In specific embodiments, the first luminescent material 210 may be configured in the transmissive mode (see e.g. embodiments I-II). In specific (other) embodiments, the first luminescent material 210 may be configured in the reflective mode (see e.g. embodiments III-VI).

The light generating system 1000 may comprise a first optical element 420 configured to focus the first device light 111 on at least part of the first luminescent material 210. In embodiments, the first luminescent material 210 may comprise a luminescent material of the type A₃B₅O₁₂:Ce, A may comprise one or more of Y, La, Gd, Tb and Lu, and B may comprise one or more of Al, Ga, In and Sc. In embodiments, a luminescent body 1200, such as a ceramic body, may comprise the first luminescent material 210.

In specific embodiments, the light generating system 1000 may further comprising a second luminescent material 220 configured to convert at least part of the first device light 111 into second luminescent material light 221 having a second centroid wavelength (λ_{c,2}) in the yellow-red wavelength range. Especially, the following may apply: λ_{c,1}<λ_{c,2}. Several configurations of the second luminescent material 220 may be possible. This is schematically shown in FIG. 2b, in relation to an embodiment wherein the first luminescent material 210 and the second luminescent material 220 are combined, e.g. in a luminescent body. Hence, in embodiments the luminescent body 1200 may comprise the second luminescent material 220. As indicated above, in embodiments the luminescent body 1200 may comprise a ceramic body.

Alternatively or additionally, in specific embodiments the light generating system 1000 may further comprises a third light generating device 130 comprising a third laser light source 30 and configured to generate third device light 131 having a third device light peak wavelength (λ₃) and having a third spectral power distribution, different from the first spectral power distribution and different from the second spectral power distribution. This is schematically depicted in embodiment VI of FIG. 1. The third device light peak wavelength λ₃ may be selected from the range of 600-650 nm, see also FIG. 2a.

In specific embodiments, the light generating system 1000 may further comprise a beam combiner 410 configured to combine at least part of the first device light 111 and at least part of the second device light 121 into a beam of device light 111,121. The term “beam combiner” may also refer to a plurality of beam combiners. When further beams of light are available, e.g. from the option third light generating device, one or more further beam combiners 410 may be applied. The beam combiner(s) 410 may be selected from the group of a dichroic beam combiner and a polarizing beam combiner.

In embodiments, the light generating system 1000 may further comprise second optics 430 configured to beam shape the system light 1001 into a beam having a full width half maximum of at maximum 2°, though other beam angles α are herein not excluded. The second optics may e.g. comprise a collimator. Referring to embodiments I and II, where these second optics 430 are schematically depicted, reference O refers to an optical axis. Would perpendicular to this optical axis a radiant flux plot be made, then the full width half maxima may provide a beam angle a of e.g. 2°.

As indicated above, the light generating system 1000 may comprise a control system. In embodiments, the control system 300 may be configured to control the first light generating device 110 and the second light generating device 120 (and the optional third light generating device 130), in specific embodiments such that in an operational mode of the light generating system 1000 the system light 1001 has a correlated color temperature selected from the range of 7000-10000 K.

In embodiments, in one of the operational modes of the light generating system 1000 the system light 1001 has a spectral power distribution in the visible wavelength range, wherein at least 5% of the spectral power may be provided by the second device light 121, at least 25% of the spectral power distribution may be provided by the first device light 111, and at least 30% of the spectral power distribution may be provided by the first luminescent material light 201.

In embodiments, in (another) one of the operational modes of the light generating system 1000 the system light 1001 has a spectral power distribution in the visible wavelength range wherein less than 1% of the spectral power may be provided by the second device light 121, at least 25% of the spectral power distribution may be provided by the first device light 111, and at least 30% of the spectral power distribution may be provided by the first luminescent material light 201.

In embodiments, in an operational mode the control system 300 controls the system light 1001 such that when increasing the correlated color temperature, a radiant flux of the system light 1001 may be increased, and that when decreasing the correlated color temperature, a radiant flux of the system light 1001 may be decreased.

Referring to also FIG. 2a, one or more of the following may apply: (i) the first device light peak wavelength λ₁ may be selected from the wavelength range of 430-460 nm, (ii) and the second device light peak wavelength λ₂ may be selected from the wavelength range of 475-485 nm. As schematically depicted, the spectral overlap is essentially zero (%). Further, there may be no third peak between the first device light peak wavelength λ₁ and the second device light peak wavelength λ₂.

Referring to FIG. 2b, schematically an embodiment of a luminescent body 1200 comprising the first luminescent material 210 and the optional second luminescent material 220. Reference 200 refers to a luminescent material in general. Further, schematically an embodiment is shown wherein the second device light 121 bypasses the first luminescent material 210 (and the second luminescent material 220). Further, schematically an embodiment is shown wherein the first device light 111 is partly transmitted by the first luminescent material 210 (and the second luminescent material 220) (more especially by the luminescent body 1200), and partly converted by the first luminescent material 210 (and the second luminescent material 220) into first luminescent material light 211 (and second luminescent material light 221).

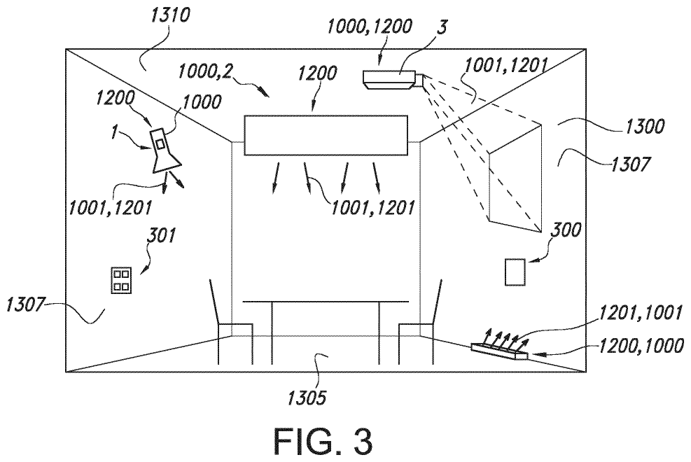

FIG. 3 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 3 also schematically depicts an embodiment of lamp 1 comprising the light generating system 1000. Reference 3 indicates a projector device or projector system, which may be used to project images, such as at a wall, which may also comprise the light generating system 1000. Hence, FIG. 3 schematically depicts embodiments of a lighting device 1200 selected from the group of a lamp 1, a luminaire 2, a projector device 3, a disinfection device, a photochemical reactor, and an optical wireless communication device, comprising the light generating system 1000 as described herein. In embodiments, such lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001. Reference 1300 refers to a space, such as a room. Reference 1305 refers to a floor and reference 1310 to a ceiling; reference 1307 refers to a wall.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating system comprising a plurality of first light generating devices, a second light generating device, a first luminescent material, and a control system, wherein:
the plurality of first light generating devices comprises a first laser light source and is configured to generate first device light having a first device light peak wavelength (λ₁) and having a first spectral power distribution; wherein the first device light peak wavelength (λ₁) is selected from the wavelength range of 425-465 nm;
the second light generating device comprises a second laser light source and is configured to generate second device light having a second device light peak wavelength (λ₂) and having a second spectral power distribution, different from the first spectral power distribution; wherein the second device light peak wavelength (λ₂) is selected from the range of 470-490 nm;
the first luminescent material is configured in a light receiving relationship with the first light generating device and is configured to convert at least part of the first device light into first luminescent material light having a luminescent material emission centroid wavelength (λ_{c,1}) within the green-yellow wavelength range; and the first luminescent material is not configured in a light receiving relationship with the second light generating device;
wherein the plurality of first light generating devices comprises a primary first light generating device and a secondary first light generating device, wherein the first luminescent material is configured in a light receiving relationship with one of the primary first light generating device and the secondary first light generating device and wherein the first luminescent material is not configured in a light receiving relationship with the other one of the primary first light generating device and the secondary first light generating device;
the light generating system is configured to generate system light comprising one or more of the first device light, the second device light, and the first luminescent material light wherein the system light has a controllable correlated color temperature;
the control system is configured to control the first light generating device and the second light generating device such that (a) in a first operational mode of the light generating system the system light has a first correlated color temperature CCT1, wherein CCT1≥4000 K, (b) in a second operational mode of the light generating system the system light has a second correlated color temperature (CCT2), wherein CCT2−CCT1≥1000 K, (c) in at least one of the operational modes, the system light has a correlated color temperature selected from the range of at least 7000 K, and (d) the system light in both operational modes has a color rendering index of at least 70.

2. The light generating system according to claim 1, wherein the first light generating device and the first luminescent material are configured such that part of the first device light is converted into the luminescent material light wherein the system light comprises (i) at least part of non-converted first device light, (ii) the second device light, and (iii) the first luminescent material light.

3. The light generating system according to claim 1, wherein the system light comprises (i) at least part of the first device light bypassing the first luminescent material (ii) the second device light, and (iii) the first luminescent material light.

4. The light generating system according to claim 1, comprising: (i) a luminescent body comprising the first luminescent material, (ii) a first thermally conductive body configured in thermal contact with the first luminescent material; and (iii) a laser bank comprising the first laser light source, the second laser light source, and a second thermally conductive body configured in thermal contact with the first laser light source and the second laser light source.

5. The light generating system according to claim 4, wherein the luminescent body comprises a ceramic body.

6. The light generating system according to claim 1, wherein the first luminescent material is configured in the reflective mode; and wherein the light generating system comprises a first optical element configured to focus the first device light on at least part of the first luminescent material.

7. The light generating system according to claim 1, wherein the first luminescent material is configured in the transmissive mode; and wherein the light generating system comprises a first optical element configured to focus the first device light on at least part of the first luminescent material.

8. The light generating system according to claim 1, wherein the first luminescent material comprises a luminescent material of the type A₃B₅O₁₂:Ce, wherein A comprises one or more of Y, La, Gd, Tb and Lu, and wherein B comprises one or more of Al, Ga, In and Sc.

9. The light generating system according to claim 1, further comprising one or more of:
a second luminescent material configured to convert at least part of the first device light into second luminescent material light having a second centroid wavelength (λ_{c,2}) in the yellow-red wavelength range; wherein λ_{c,1}<λ_{c,2}; and
a third light generating device comprising a third laser light source and configured to generate third device light having a third device light peak wavelength (λ3) and having a third spectral power distribution, different from the first spectral power distribution and different from the second spectral power distribution; wherein the third device light peak wavelength (λ3) is selected from the range of 600-650 nm.

10. The light generating system according to claim 1, further comprising a beam combiner configured to combine at least part of the first device light and at least part of the second device light into a beam of device light; wherein the beam combiner is selected from the group of a dichroic beam combiner and a polarizing beam combiner.

11. The light generating system according to claim 1, further comprising second optics configured to beam shape the system light into a beam having a full width half maximum of at maximum 2°; and wherein the first device light peak wavelength (λ₁) is selected from the wavelength range of 430-460 nm, and/or wherein the second device light peak wavelength (λ₂) is selected from the wavelength range of 475-485 nm.

12. The light generating system according to claim 1, wherein the control system is configured to control the first light generating device and the second light generating device such that in an operational mode of the light generating system the system light has a correlated color temperature selected from the range of 7000-10000 K.

13. The light generating system according to claim 1, wherein:
in one of the operational modes of the light generating system the system light has a spectral power distribution in the visible wavelength range wherein at least 5% of the spectral power is provided by the second device light wherein at least 25% of the spectral power distribution is provided by the first device light and wherein at least 30% of the spectral power distribution is provided by the first luminescent material light; and/or
in one of the operational modes of the light generating system the system light has a spectral power distribution in the visible wavelength range wherein less than 1% of the spectral power is provided by the second device light; wherein at least 25% of the spectral power distribution is provided by the first device light, and wherein at least 30% of the spectral power distribution is provided by the first luminescent material light.

14. The light generating system according to claim 1, wherein in an operational mode the control system controls the system light such that when increasing the correlated color temperature, a radiant flux of the system light is increased, and that when decreasing the correlated color temperature, a radiant flux of the system light is decreased.

15. A lighting device selected from the group of a lamp (1), a luminaire (2), a projector device (3), comprising the light generating system according to claim 1.
